(19) United States
(12) Patent Application Publication
(10) Pub. No.: US 2015/0263252 A1
(43) Pub. Date: Sep. 17, 2015

(54) OPTICAL ENHANCEMENT OF LIGHT EMITTING DEVICES

(71) Applicant: Invensas Corporation, San Jose, CA (US)

(72) Inventors: Liang Wang, Milpitas, CA (US); Masud Beroz, Morrisville, NC (US); Ilyas Mohammed, Santa Clara, CA (US)

(21) Appl. No.: 14/727,810

(22) Filed: Jun. 1, 2015

Related U.S. Application Data
(62) Division of application No. 13/541,615, filed on Jul. 3, 2012.

(51) Int. Cl. H01L 33/58; H01L 51/52; H01L 33/44

(52) U.S. Cl. CPC H01L 33/58; H01L 33/44; H01L 51/5268; H01L 2933/0083; H01L 2251/5369

(57) ABSTRACT

Optical enhancement of light emitting devices. In accordance with an embodiment of the present invention, an apparatus includes an optical enhancement layer comprising nanoparticles. Each of the nanoparticles includes an electrically conductive core surrounded by an electrically insulating shell. The optical enhancement layer is disposed on a top semiconductor layer in a preferred path of optical emission of a light emitting device. The nanoparticles may enhance the light emission of the light emitting device due to emitter-surface plasmon coupling.

### FIELD OF INVENTION

Embodiments of the present invention relate to the field of integrated circuit design and manufacture. More specifically, embodiments of the present invention relate to systems and methods for optical enhancement of light emitting devices.

### BACKGROUND

Improved efficiency of light emitting devices is desired.

### SUMMARY OF THE INVENTION

Therefore, what is needed are systems and methods for optical enhancement of light emitting devices. What is additionally needed are systems and methods for optical enhancement of light emitting devices that improve light emission, light extraction and/or efficiency of light emitting devices. A further need exists for systems and methods for optical enhancement of light emitting devices that are compatible and complementary with existing systems and methods of integrated circuit design, manufacturing and test. Embodiments of the present invention provide these advantages.

In accordance with an embodiment of the present invention, an apparatus includes an optical enhancement layer comprising nanoparticles. Each of the nanoparticles includes an electrically conductive core surrounded by an electrically insulating shell. The optical enhancement layer is disposed on a top semiconductor layer in a preferred path of optical emission of a light emitting device. The nanoparticles may enhance the light emission of the light emitting device due to emitter-surface plasmon coupling.

In accordance with another embodiment of the present invention, an apparatus includes an insulating layer disposed on a semiconductor layer. The insulating layer is opposite a light emitting layer of a light emitting device. A layer of conductive nanoparticles is disposed on the insulating layer. The nanoparticles may be electrically coupled to one another.

In accordance with a method embodiment of the present invention, a plurality of nanoparticles is formed. Each nanoparticle includes a conductive core surrounded by an insulating shell. A top semiconductor layer is constructed over a light emitting layer of a light emitting device. The plurality of nanoparticles is applied over the top semiconductor layer. The plurality of nanoparticles may be sprayed onto the top semiconductor layer.

### BRIEF DESCRIPTION OF THE DRAWINGS

The accompanying drawings, which are incorporated in and form a part of this specification, illustrate embodiments of the invention and, together with the description, serve to explain the principles of the invention. Unless otherwise noted, the drawings are not drawn to scale

FIG. 1A illustrates an optically enhanced light emitting diode, in accordance with embodiments of the present invention.

FIG. 1B illustrates an optically enhanced light emitting diode, in accordance with embodiments of the present invention.

FIG. 1C illustrates a segment of another arrangement of an optically enhanced light emitting diode, in accordance with embodiments of the present invention.

FIG. 1D illustrates a segment of a further arrangement of an optically enhanced light emitting diode, in accordance with embodiments of the present invention.

FIG. 2A illustrates a cross-sectional view of a metal nanoparticle with a dielectric coating, in accordance with embodiments of the present invention.

FIG. 2B illustrates a cross-sectional view of a metal nanoparticle with a dielectric coating and current spreading material, in accordance with embodiments of the present invention.

FIG. 3A illustrates an optically enhanced light emitting diode, in accordance with embodiments of the present invention.

FIG. 3B illustrates an optically enhanced light emitting diode, in accordance with embodiments of the present invention.

FIG. 4 illustrates a method of producing a light emitting diode, in accordance with embodiments of the present invention.

FIG. 5 illustrates an exemplary application of optically enhanced light emitting diodes, in accordance with embodiments of the present invention.

### DETAILED DESCRIPTION

Reference will now be made in detail to various embodiments of the present invention, examples of which are illustrated in the accompanying drawings. While the invention will be described in conjunction with these embodiments, it is understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the invention, numerous specific details are set forth in order to provide a thorough understanding of the invention. However, it will be recognized by one of ordinary skill in the art that the invention may be practiced without these specific details. In other instances, well known methods, procedures, components, and circuits have not been described in detail as not to unnecessarily obscure aspects of the invention.

### NOTATION AND NOMENCLATURE

Some portions of the detailed descriptions which follow (e.g., process 400) are presented in terms of procedures, steps, logic blocks, processing, and other symbolic representations of operations on data bits that may be performed on computer memory. These descriptions and representations are the means used by those skilled in the data processing arts to most effectively convey the substance of their work to others skilled in the art. A procedure, computer executed step, logic block, process, etc., is here, and generally, conceived to be a self-consistent sequence of steps or instructions leading to a desired result. The steps are those requiring physical manipulations of physical quantities. Usually, though not necessarily, these quantities take the form of electrical or magnetic signals capable of being stored, transferred, combined, compared, and otherwise manipulated in a computer system. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussions, it is appreciated that throughout the present invention, discussions utilizing terms such as “attaching” or “processing” or “singulating” or “processing” or “forming” or “roughening” or “filling” or “accessing” or “performing” or “generating” or “adjusting” or “creating” or “executing” or “continuing” or “indexing” or “processing” or “computing” or “translating” or “calculating” or “determining” or “measuring” or “gathering” or “running” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Although exemplary embodiments in accordance with the present invention are illustrated in terms of a gallium nitride light emitting diode, such examples are not limiting. It is to be appreciated that embodiments in accordance with the present invention are well suited to a variety of devices employing a variety of materials, including, for example, organic light emitting devices (OLED), group III-V light emitting diodes, and/or devices employing multiple quantum wells and the like.

As used herein, and in the semiconductor arts, the term “nanoparticle” is used to refer to or to describe particles with sizes, e.g., diameters, measured in nanometers (10⁻⁹ meters, nm). As per conventional engineering notation, particle sizes larger than 1000 nm are described in terms of micrometers (10⁻⁶ meters, μm), and are not considered “nano” particles. Nanoparticles may exhibit size-related properties that differ significantly from those observed in larger particles or bulk materials.

### Optical Enhancement of Light Emitting Devices

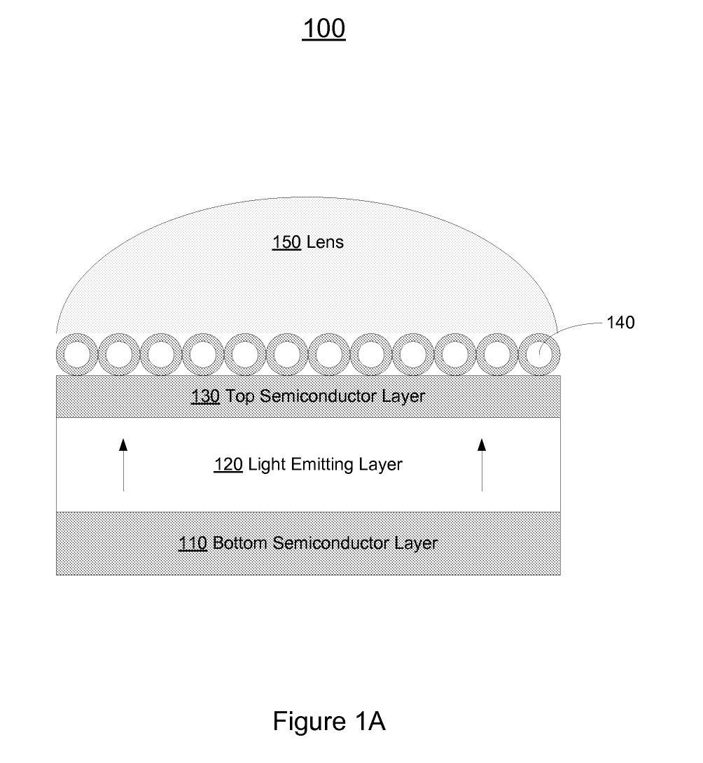

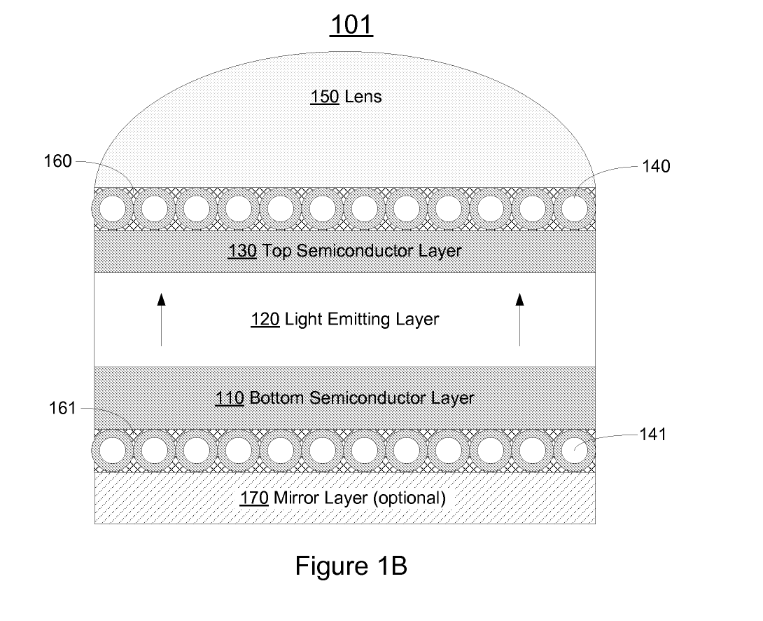

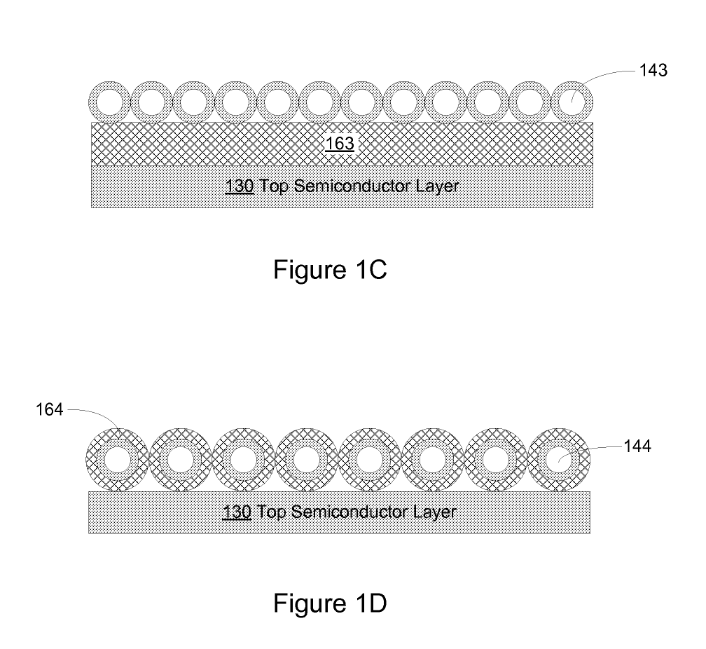

FIG. 1A illustrates an optically enhanced light emitting diode (LED) 100, in accordance with embodiments of the present invention. Diode 100 may be characterized as an organic light emitting diode (OLED), or as an inorganic light emitting diode. The preferred path for light emission of diode 100 is out of the top, as illustrated in FIG. 1A. Diode 100 comprises a bottom semiconductor layer 110, e.g., a semiconductor layer directly contacting a cathode terminal. Layer 110 may comprise multiple materials, laid down in different operations, and may be formed by any suitable process(es) and may comprise any suitable semiconductor material, including, for example, gallium arsenide (GaAs), gallium phosphide (GaP) and/or gallium nitride (GaN). Layer 110 is not in a preferred optical path of the diode 100. Layer 110 may be mirrored on its bottom surface, to reflect light back in a more preferred direction.

Diode 100 also comprises a light emitting layer 120. Layer 120 may comprise multiple materials, laid down in different operations, and may be formed by any suitable process(es) and may comprise any suitable semiconductor material, including, for example, indium gallium nitride (InGaN). Layer 120 may comprise a multiple quantum well (MQW) structure, for example. Diode 100 further comprises a top semiconductor layer 130, e.g., a semiconductor layer directly contacting an anode terminal. Layer 130 may comprise multiple materials, laid down in different operations, and may be formed by any suitable process(es) and may comprise any suitable semiconductor material, including, for example, gallium arsenide (GaAs), gallium phosphide (GaP) and/or gallium nitride (GaN). Top semiconductor layer 130 is in a preferred path of optical emission for the light emitting diode 100.

Diode 100 may optionally comprise a lens 150, e.g., for gathering light and/or matching indices of refraction. An optional phosphor (not shown) may be placed below, within, or on top of lens 150.

In accordance with embodiments of the present invention, diode 100 comprises a layer 140 of metal nanoparticles with a dielectric coating in contact with top semiconductor layer 130. The layer 140 enhances light emission due to emitter-surface plasmon coupling.

Surface plasmons are the collective oscillation of free electrons in a metal. They occur at the interfaces of metals and semiconductors or metals and dielectrics. Because of the large free electron density of metals, surface plasmons show strong resonances at optical frequencies and thus couple to incoming photons. When the exciton dipole energies of a light-emitting layer and the surface plasmon energy of a metal are similar, the excited dipole energies in the light-emitting layer can be transferred into surface plasmon modes of the metal. If the dissipation rate of surface plasmons is low, then the surface plasmons will efficiently capture dipole oscillator energy in the light-emitting layer and then radiate effectively. Since the density of states of surface plasmon mode is much larger, this process is much faster than the recombination rate of the exciton dipole in the light-emitting layer. Therefore the spontaneous emission rate in the light-emitting layer is increased, which leads to an enhancement of light emission by coupling between surface plasmons and a light emitting layer.

For a continuous metal layer, the surface plasmon forms a propagating wave and the dissipation rate is relatively high. The resonance wavelength and optical properties are determined primarily by the type of metal and thus cannot be easily adjusted. In contrast, for a distribution, e.g., an array, of metal nanoparticles, with or without a dielectric shell, the surface plasmon mode exists by means of localized surface plasmons where the dissipation rate is low. Accordingly, the resonance wavelength and the resultant optical properties may be varied by adjusting the type, size, shape, and interparticle distance of the metal (or metal-dielectric) nanoparticles.

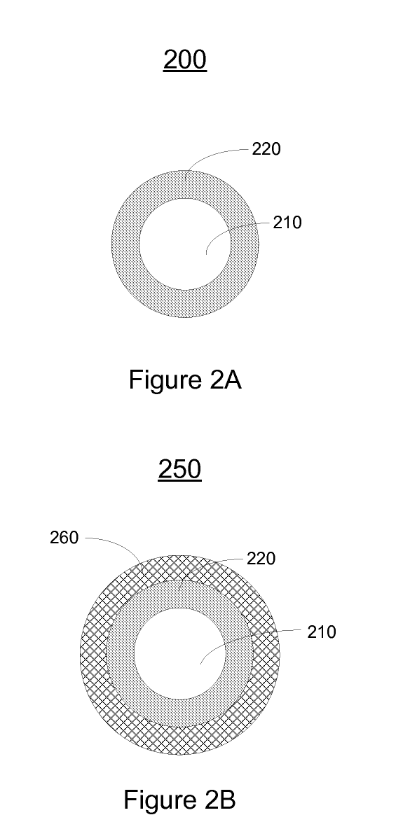

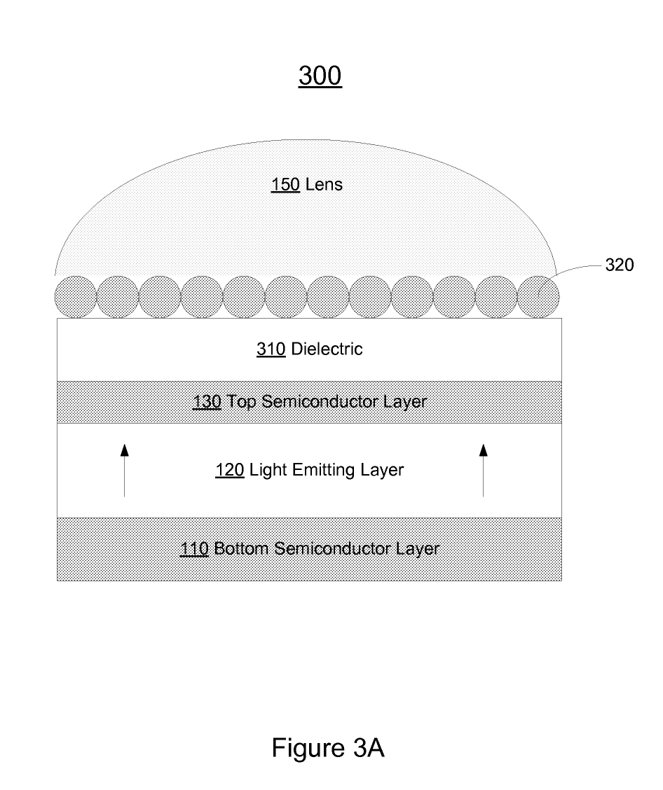

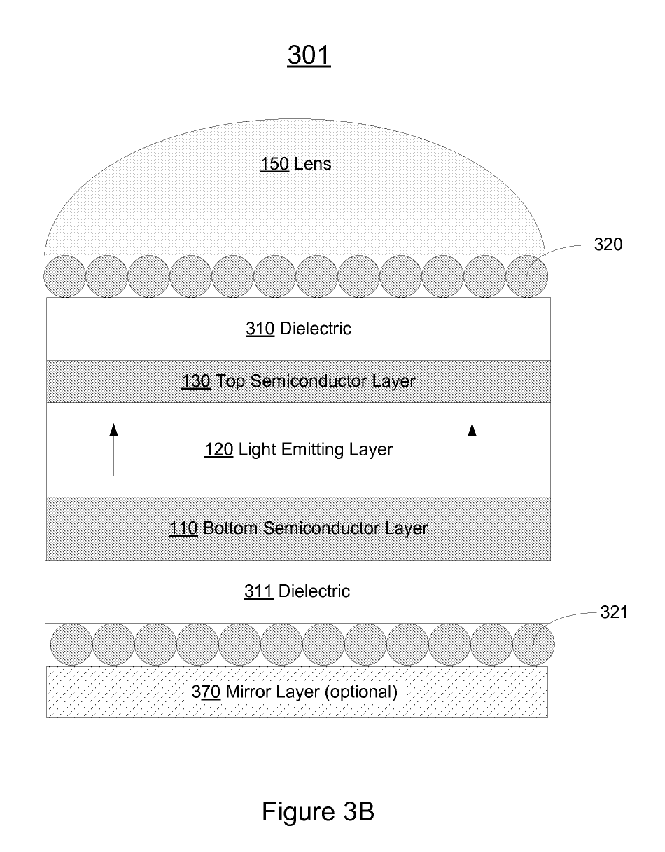

If there is an electrically conductive path, e.g., from a semiconductor layer or an electrode (cathode or anode) to a conductive core carrying surface plasmons, the surface plasmons may leak, resulting in a high dissipation rate. Accordingly, light emission enhancement due to plasmon coupling with an emitting layer may be greatly reduced or vanish. In accordance with embodiments of the present invention, electrical insulating structures, for example, a dielectric shell surrounding a conductive core of a nanoparticle (e.g., 220 in FIG. 2A) or a dielectric layer between a semiconductor layer and a metal nanoparticle array (e.g., 310 and/or 311 in FIG. 3B), are provided to prevent surface plasmons from leaking.

The coupling between surface plasmons in metal and dipole energies in a light emitting layer decays with distance. Accordingly, in order to enhance light emission, the distance between the light-emitting layer and the metal (or metal-dielectric) nanoparticles must be within the range of an effective length. This effective length may depend on the dielectric constants of the metal and of the dielectric, as well as on the emission wavelength and refractive index of the media materials (semiconductor, dielectric layer on top of semiconductor and/or the dielectric shell of a nanoparticle). In the case of a continuous metal layer, this effective length can be quite different for an indium gallium nitride (InGaN) based LED and organic LEDs, e.g., about 150 nm for an InGaN based blue LED, and about 2 μm for organic LEDs. If the distance between the light-emitting layer and the metal (or metal-dielectric) nanoparticles exceeds this range of effective length, light output may still be enhanced; however, the main effect is not light emission enhancement due to coupling between surface plasmon and light emitting layer. Rather, in such a case, the enhancement is primarily due to the scattering effect of nanoparticles reducing total internal reflection.

In addition, the layer 140 has a low dissipation rate, e.g., due to the insulating property of the dielectric coating. Further, due to the scattering structure of layer 140 and its high transparency, incidences of total internal reflection are reduced in comparison to the conventional art, and light extraction is enhanced by this mechanism as well. Layer 140 of metal nanoparticles with a dielectric coating may be applied by any suitable process, including, for example, spin coating, blade-casting, ink-jet printing, screen printing, micro-contact printing, spraying in a solvent, transport deposition through a carrier gas and/or electrophoretic deposition (EPD).

FIG. 1B illustrates an optically enhanced light emitting diode (LED) 101, in accordance with embodiments of the present invention. Diode 101 illustrates the addition of optional electrical enhancements in addition to the optical enhancements of diode 100 (FIG. 1A). Diode 101 may optionally comprise a current spreading material 160, in accordance with embodiments of the present invention. Optional current spreading material 160 may function to improve current injection and current uniformity, which may enable greater overall efficiency of a light emitting device.

Optional current spreading material 160 is located between the top semiconductor layer 130 and lens 150. Optional current spreading material 160 may fill “voids” between the nanoparticles with a dielectric coating of layer 140, for example. Optional current spreading material 160 may comprise, for example, a transparent conductive oxide (TCO), a thin metal grating and/or a transparent conducting polymer, e.g., poly(3,4-ethylenedioxythiophene) poly(styrenesulfonate) (PEDOT:PSS). Due to the scattering function of the layer 140 of metal nanoparticles with a dielectric coating, there will not be total internal reflection from the top semiconductor layer 130 into current spreading material 160. However, total internal reflection may occur from current spreading material 160 into lens 150, for example, if the current spreading material is thick enough to form a continuous layer covering all the nanoparticles. Such internal reflection may be reduced or eliminated by grooving and/or roughening the surface(s) of current spreading material 160.

In accordance with embodiments of the present invention, diode 101 may optionally comprise a layer 141 of metal nanoparticles with a dielectric coating in contact with bottom semiconductor layer 110. Layer 141 is comparable to layer 140. In accordance with embodiments of the present invention, diode 101 may optionally comprise a current spreading material 161. Current spreading material 161 is comparable to current spreading material 160. Optional layers 141 and/or 161 should be placed above an optional mirror layer 170 on the bottom side of light emitting diode 101, and may further enhance light output.

FIG. 1C illustrates a segment of another arrangement of an optically enhanced light emitting diode, in accordance with embodiments of the present invention. In the embodiment of FIG. 1C, current spreading material 163, which is generally analogous to current spreading material 160 (FIG. 1B) forms a layer between top semiconductor layer 130 (or bottom semiconductor layer 110, as illustrated in FIG. 1B) and layer 143 of metal nanoparticles with a dielectric coating. Layer 143 is generally analogous to layer 140 (FIG. 1B). It is appreciated that current spreading material 163 is formed in contact with a semiconductor layer, on a side opposite of a light emitting layer. Layer 143 and layer 163 are considered to form an optical enhancement layer, in accordance with embodiments of the present invention.

FIG. 1D illustrates a segment of a further arrangement of an optically enhanced light emitting diode, in accordance with embodiments of the present invention. In the embodiment of FIG. 1D, current spreading material 164, which is generally analogous to current spreading material 160 (FIG. 1B) is formed as an outer shell over nanoparticle 144, a dielectric coating surrounding a conductive core, which is generally analogous to the nanoparticles of layer 140 (FIG. 1B). The layer of nanoparticles with current spreading outer shells may be formed on a top semiconductor layer 130, or on a bottom semiconductor layer 110 (FIG. 1B), on a side opposite of a light emitting layer.

FIG. 2A illustrates a cross-sectional view of a metal nanoparticle with a dielectric coating 200, in accordance with embodiments of the present invention. A plurality of instances of particle 200 may form layer 140 of FIG. 1A, for example. Metal nanoparticle with a dielectric coating 200 may be generally spherical, although an exact spherical shape is not required. Metal nanoparticle with a dielectric coating 200 may have a diameter in the range of about 10 nm to 300 nm.

Metal nanoparticle with a dielectric coating 200 comprises a metal nanoparticle 210, also known as or referred to as a “core.” Metal nanoparticle 210 should be electrically conductive. Metal nanoparticle 210 may have a diameter of about 2 nm to 300 nm. The metal nanoparticle 210 may comprise, for example, gold (Au), silver (Ag), palladium (Pd), titanium (Ti), platinum (Pt), aluminum (Al), nickel (Ni), chrome (Cr), zirconium (Zr), zinc (Zn), copper (Cu), tungsten (W), molybdenum (Mo), cobalt (Co) or the like. The metal nanoparticle 210 may also comprise, for example, metal alloys, e.g., Al—Cu. In general, the enhancement effect will vary with the materials selected. However, the core particle size should be less than the wavelengths of interest.

Metal nanoparticle 210 may be formed by vacuum evaporation, e.g., via thermal, e-beam or sputtering processes, of a nanoscale metal thin film, followed by annealing. The thermal annealing enables the nanoparticles to be formed by isolating from each other by means of the self-aggregation of the metal.

Metal nanoparticle 210 may also be formed by a nanoimprint technique, through etching, lift-off or direct depositioin processes. Further, metal nanoparticle 210 may be formed by directly spin coating of a nanoparticle suspension, self-assembly or an electrophorretic deposition process.

Metal nanoparticle with a dielectric coating 200 further comprises a dielectric coating 220, surrounding metal nanoparticle 210, also known as or referred to as a “shell.” Dielectric coating 220 may have a thickness of about 2 nm to 100 nm. Dielectric coating 220 may comprise, for example, silica (SiO₂), titania (TiO₂), alumina (Al₂O₃), nickel oxide (NiO), chromium dioxide (CrO₂), cobalt monoxide (CoO), tungsten trioxide (WO₃), molybdenum trioxide (MoO₃), zinc oxide (ZnO), zinc sulfide (ZnS), copper sulfide (CuS), zirconium dioxide (ZrO₂), and the like. Dielectric coating 220 over metal core 210 may be formed by a variety of methods, including, for example, in-situ oxidization of a reactive metal, chemical vapor deposition (CVD), or through wet chemistry, such as polymerization, sol-gel method, reverse micelle method, mechanochemical/sonochemical synthesis, electrochemical processes, and the like. Exemplary processes for forming particle 200, e.g., a dielectric coating 220 over a metal nanoparticle 210, are commercially available from nanoComposix, Inc. of San Diego, Calif. and Mantis Deposition Ltd. of Oxon, United Kingdom.

FIG. 2B illustrates a cross-sectional view of a metal nanoparticle with a dielectric coating and current spreading material 260, in accordance with embodiments of the present invention. For example, particle 260 may be suitable for the embodiment of FIG. 1D. In addition to core 210 and shell 220, particle 260 comprises an outer shell of current spreading material, e.g., material analogous to current spreading material 160 (FIG. 1B).

FIG. 3A illustrates an optically enhanced light emitting diode (LED) 300, in accordance with embodiments of the present invention. Diode 300 may be characterized as an organic light emitting diode (OLED), or as an inorganic light emitting diode. Diode 300 comprises a bottom semiconductor layer 110. Layer 110 may comprise multiple materials, laid down in different operations, and may be formed by any suitable process(es) and may comprise any suitable semiconductor material, including, for example, gallium arsenide (GaAs), gallium phosphide (GaP) and/or gallium nitride (GaN).

Diode 300 also comprises a light emitting layer 120. Layer 120 may comprise multiple materials, laid down in different operations, and may be formed by any suitable process(es) and may comprise any suitable semiconductor material, including, for example, indium gallium nitride (InGaN). Diode 300 further comprises a top semiconductor layer 130. Layer 130 may comprise multiple materials, laid down in different operations, and may be formed by any suitable process(es) and may comprise any suitable semiconductor material, including, for example, gallium arsenide (GaAs), gallium phosphide (GaP) and/or gallium nitride (GaN).

Diode 300 may optionally comprise a lens 150, e.g., for gathering light and/or matching indices of refraction.

In accordance with embodiments of the present invention, diode 300 comprises a dielectric layer 310, adjacent to top semiconductor layer 130. Dielectric layer 310 functions to match an index of refraction of the light emitting layers of diode 300 to an index of refraction of optional lens 150 and/or air. In accordance with embodiments of the present invention, the index of refraction for dielectric layer 310 should be equal to or greater than an index of refraction for the top semiconductor layer 130. Dielectric layer 310 should have a thickness suitable for plasmon enhancement by layer 320 of metal nanoparticles, further described below. For example, dielectric layer 310 may generally, but not necessarily, be less than a wavelength of interest.

For example, top semiconductor layer 130 may comprise gallium nitride (GaN). A typical index of refraction for such a gallium nitride (GaN) layer is about 2.45. In order to match or exceed such an index of refraction, a group of materials with refractive index greater than about 2.4 may be used in dielectric layer 310. Such materials may include, for example, cadmium indate (Cdln₂O₄), index of refraction 2.58, Strontium titanate (SrTiO₃), index of refraction 2.472, titania (TiO₂), index of refraction 2.44 and/or zinc sulfide (ZnS), index of refraction 2.419.

In addition, in accordance with embodiments of the present invention, light emitting diode 300 comprises a layer 320 of metal nanoparticles. It is to be appreciated that the metal nanoparticles of layer 320 are not coated with a dielectric shell, in contrast to metal nanoparticle with a dielectric coating 200, as illustrated in FIG. 2.

In accordance with embodiments of the present invention, the metal nanoparticles of layer 320 may be electrically conductive, and may be in electrical contact with one another. The metal nanoparticles of layer 320 may have a diameter of about 10 nm to 200 nm. The metal nanoparticles of layer 320 may comprise, for example, gold (Au), silver (Ag), palladium (Pd), titanium (Ti), platinum (Pt), aluminum (Al), nickel (Ni), chrome (Cr), zirconium (Zr), zinc (Zn), copper (Cu), tungsten (W), molybdenum (Mo), cobalt (Co) or the like. The metal nanoparticles of layer 320 may also comprise, for example, metal alloys, e.g., Al—Cu.

In accordance with embodiments of the present invention, dielectric layer 310 and layer 320 of metal nanoparticles enhance light emission from light emitting diode 300 due to emitter-surface plasmon coupling and a low dissipation rate of the nanoparticle array, e.g., due to the insulating property of the dielectric coating. In addition, light extraction is improved due to reduced incidence of total internal reflection at the dielectric 310/lens 150 interface by the scattering structure of the nanoparticle array.

FIG. 3B illustrates an optically enhanced light emitting diode (LED) 301, in accordance with embodiments of the present invention. Diode 301 illustrates the addition of optional optical enhancements over diode 300 (FIG. 3A). Diode 301 may optionally comprise a dielectric layer 311, in accordance with embodiments of the present invention. Optional dielectric layer 311 is below and in contact with bottom semiconductor layer 110. Layer 311 is comparable to layer 310 (FIG. 3A).

In accordance with embodiments of the present invention, diode 301 may optionally comprise a layer 321 of metal nanoparticles. Layer 321 of metal nanoparticles is comparable to layer 320 (FIG. 3A). Optional layers 311 and/or 321 should be placed above an optional mirror layer 370 on the bottom side of light emitting diode 301, and may further enhance light output.

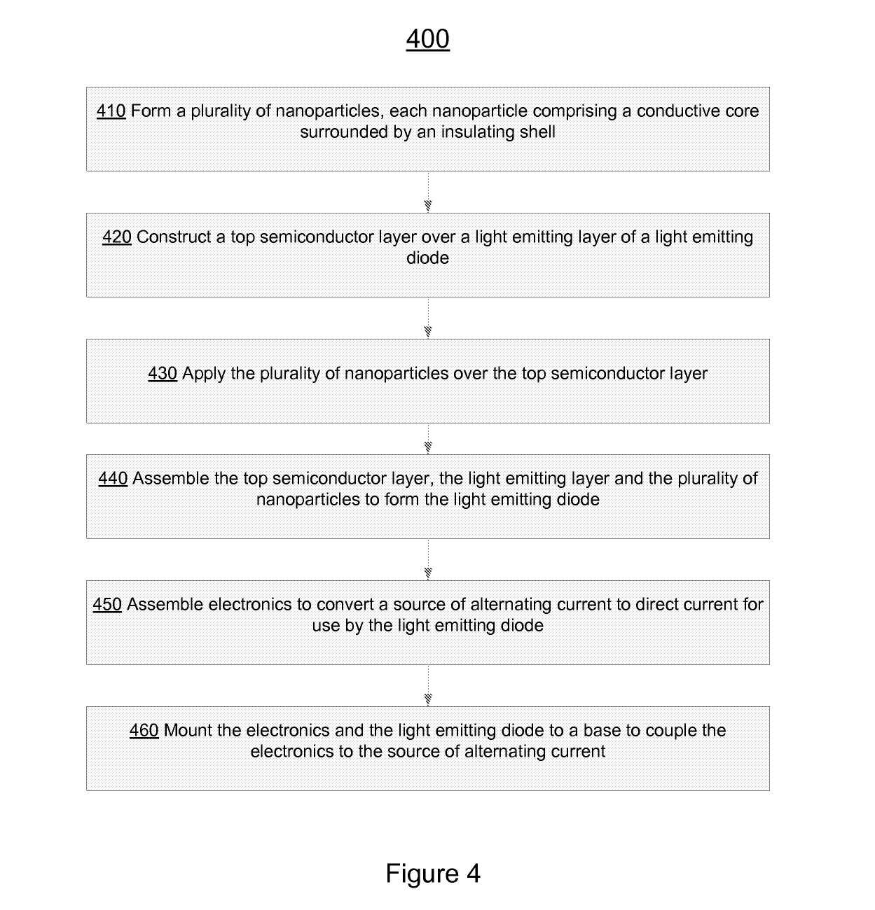

FIG. 4 illustrates a method 400 of producing a light emitting diode, in accordance with embodiments of the present invention. In 410, a plurality of nanoparticles is formed. Each nanoparticle comprises a conductive core surrounded by an insulating shell. The core may be metallic. For example, nanoparticle with a dielectric coating 200 (FIG. 2) may be formed. The forming of the nanoparticles may utilize or include a variety of methods, including, for example, in-situ oxidation of the conductive core, chemical vapor deposition (CVD), or wet chemistry, such as polymerization, sol-gel method, reverse micelle method, mechanochemical/sonochemical synthesis, electrochemical processes, spin coating of a nanoparticle suspension, and/or an electrophorretic deposition process. Embodiments in accordance with the present invention are well suited to other processes.

In 420, a top semiconductor layer is constructed over a light emitting layer of a light emitting diode. The top semiconductor layer typically does not emit light, but rather serves as a source or sink for charge carriers. For example, top semiconductor layer 130 (FIG. 1A) may be constructed.

In 430, the plurality of nanoparticles is applied over the top semiconductor layer. For example, layer 140 of metal nanoparticles with a dielectric coating is applied over top semiconductor layer 130, as illustrated in FIG. 1A. The application may comprise coating the nanoparticles onto the top semiconductor layer through a variety of processes including, for example, spin coating, blade-casting, ink-jet printing, screen printing, micro-contact printing, spraying in a solvent, transport deposition through a carrier gas, in accordance with embodiments of the present invention.

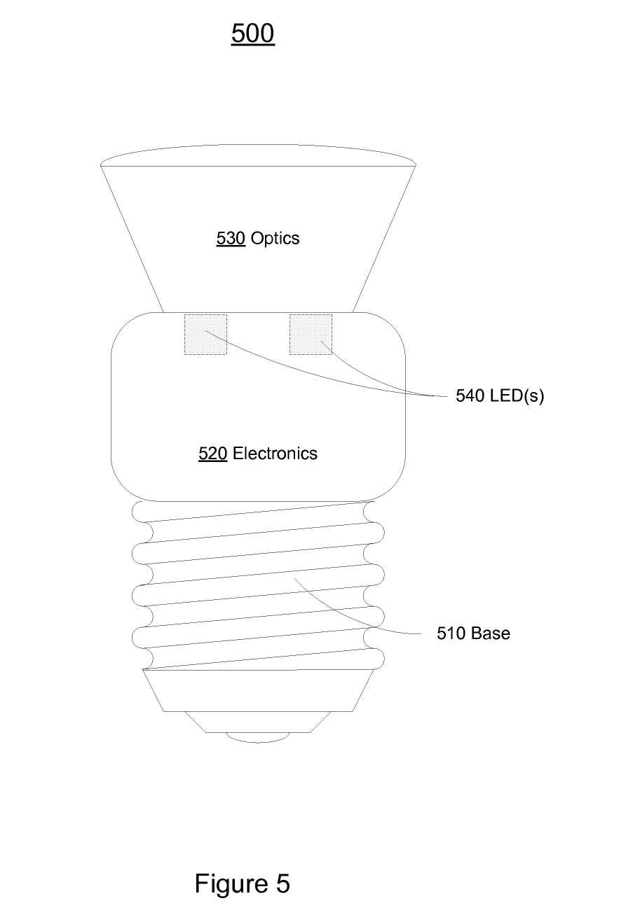

In optional 440, the top semiconductor layer, the light emitting layer and the plurality of nanoparticles are assembled to form the light emitting diode, for example, light emitting diode 100 of FIG. 1A. In optional 450, electronics to convert a source of alternating current to direct current for use by the light emitting diode are assembled. For example, electronics 520 of FIG. 5 are assembled.

In optional 460, the electronics and the light emitting diode are mounted to a base to couple the electronics to the source of alternating current. The base may correspond to base 510 of FIG. 5, for example.

FIG. 5 illustrates an exemplary application of optically enhanced light emitting diodes, in accordance with embodiments of the present invention. Light appliance 500 is well suited to a variety of lighting applications, including domestic, industrial, automobile, aircraft and landscape lighting. Light appliance 500 is also well suited to stage or theatrical lighting. Light appliance 500 comprises a base 510. As illustrated, base 510 is an Edison type base. It is appreciated that embodiments in accordance with the present invention are well suited to other types of bases, including, for example, GU, bayonet, bipin, wedge, stage pin or other types of bases.

Light appliance 500 additionally comprises a body portion 520 that houses power conditioning electronics (not shown) that convert 110 V AC input electrical power (or 220 V AC, or other selected input electrical power) to electrical power suitable for driving a plurality of light emitting diode devices 540. Body portion 520 may also comprise, or couple to, optional heat sink features (not shown).

Light appliance 500 may additionally comprise optional optics 530. Optics 530 comprise diffusers and/or lenses for focusing and/or diffusing light from the plurality of light emitting diode devices 540 into a desired pattern.

Light appliance 500 comprises a plurality of light emitting diode devices. Individual LEDs of a plurality of light emitting diode devices may correspond to assemblies previously described herein. For example light appliance 500 may include one or more instances of light emitting diodes 100 (FIG. 1A), 101 (FIG. 1B), 300 (FIG. 3A) and/or 301 (FIG. 3B). It is appreciated that not all instances of light emitting diodes within light applicant 500 need be identical.

It is to be further appreciated that appliance 500 may comprise a plurality of individual, different, LED devices. For example, one instance of an electronic device may be a blue light emitting diode formed on a sapphire substrate. Another instance of an electronic device may be a green light emitting diode formed on a gallium phosphide (GaP) substrate. Another instance of an electronic device may be a red light emitting diode formed on a gallium arsenide (GaAs) substrate. The three instances of electronic devices may be arranged such that the light from such three colors may be combined to produce a variety of spectral colors. For example, a plurality of light emitting diode devices may operate in combination to produce a “white” light output.

In accordance with embodiments of the present invention, light appliance 500 may include additional electronics associated with the LED devices. In one exemplary embodiment, such additional electronics may comprise circuits to implement a white balance among tri-color LEDs.

Embodiments in accordance with the present invention provide systems and methods for optical enhancement of light emitting devices. In addition, embodiments in accordance with the present invention provide systems and methods for optical enhancement of light emitting devices that improve light emission, light extraction and/or efficiency of light emitting devices. Further, embodiments in accordance with the present invention provide for systems and methods for optical enhancement of light emitting devices that are compatible and complementary with existing systems and methods of integrated circuit design, manufacturing and test.

Various embodiments of the invention are thus described. While the present invention has been described in particular embodiments, it should be appreciated that the invention should not be construed as limited by such embodiments, but rather construed according to the below claims.

What is claimed is:

1. An apparatus comprising:
an optical enhancement layer comprising nanoparticles and a current spreading material that is an electrical conductor;
each of said nanoparticles comprise an electrically conductive core surrounded by an electrically insulating shell; and said optical enhancement layer disposed on a top semiconductor layer in a preferred path of optical emission of a light emitting device.

2. The apparatus of claim 1 wherein the current spreading material is made of metal or metal alloy.

3. The apparatus of claim 1 wherein the current spreading material is made of a transparent conductive oxide.

4. The apparatus of claim 1 wherein the current spreading material is electrically connected to an electrode for supplying electrical power to the apparatus.

5. The apparatus of claim 1 wherein the current spreading material is a continuous layer that covers at least a portion of the top semiconductor layer.

6. The apparatus of claim 1 wherein the current spreading material is made is a pattern of grid lines such that said nanoparticles are disposed in the area of the grid lines.

7. The apparatus of claim 1 wherein said nanoparticles are substantially spherical.

8. The apparatus of claim 1 wherein said nanoparticles have a diameter in the range of about 2 nm to 500 nm.

9. The apparatus of claim 1 wherein said core has a diameter in the range of about 2 nm to 300 nm.

10. The apparatus of claim 1 wherein said shell has a thickness in the range of about 2 nm to 100 nm.

11. The apparatus of claim 1 wherein said cores are electrically isolated from one another.

12. The apparatus of claim 1 wherein said cores are electrically isolated from said top semiconductor layer.

13. The apparatus of claim 1 wherein said optical enhancement layer is separate from said top semiconductor layer.

14. The apparatus of claim 1 wherein optical enhancement layer is disposed on said top semiconductor layer opposite of a light emitting layer.

15. The apparatus of claim 1 wherein said current spreading material fills voids between said nanoparticles in said optical enhancement layer.

16. The apparatus of claim 1 wherein each said nanoparticle comprises an outer shell comprising said current spreading material.

17. The apparatus of claim 1 wherein said current spreading material is disposed in contact with a semiconductor layer separate from said nanoparticles.

18. The apparatus of claim 1 wherein said nanoparticles are within an effective length of a light emitting layer to achieve emitter-surface plasmon coupling.

19. The apparatus of claim 1 further comprising electronics to convert a source of alternating current to direct current for use by said light emitting device; and a base to couple said electronics to said source of alternating current.

20. The apparatus of claim 1, wherein the optical enhancement layer further comprises a layer with a dielectric coating.
